(19) United States
(12) Patent Application Publication
(10) Pub. No.: US 2021/0294491 A1
(43) Pub. Date: Sep. 23, 2021

(54) PROCESSING APPARATUS

(71) Applicant: DISCO CORPORATION, Tokyo (JP)

(72) Inventors: Sayuki OHTAKA, Tokyo (JP); Tasuku KOJO, Tokyo (JP)

(21) Appl. No.: 17/194,497

(22) Filed: Mar. 8, 2021

(30) Foreign Application Priority Data
Mar. 19, 2020 (JP) 2020-050021

(51) Int. Cl. G06F 3/0488; G06F 3/0482; G06F 3/0481; G06F 3/0484

(52) U.S. Cl. CPC G06F 3/04886; G06F 3/0482; G06F 3/04817; G06F 3/0484; G06F 3/04812

(57) ABSTRACT

A processing apparatus includes a touch panel that accepts an operator's operation, and a control unit that drives each of mechanisms by selection by the operator of an operation button displayed on the touch panel. The touch panel is configured such as to be able to display a progress confirmation screen on which a plurality of operation buttons are aligned, and displays the operation buttons which are selected by the operator and the works relevant to which have been completed and the operation buttons the works relevant to which have not been completed by the operator in a discriminable manner.

### BACKGROUND OF THE INVENTION

### Field of the Invention

The present invention relates to a processing apparatus.

### Description of the Related Art

There has been known a processing apparatus which requires an operator to carry out and complete a plurality of works (see Japanese Patent Laid-open No. 2010-049466).

### SUMMARY OF THE INVENTION

However, in such a processing apparatus, it has been necessary to manage whether or not a plurality of works to be carried out have been completed or whether or not the plurality of works are being sequentially carried out according to a work sequence, with an operator's handwritten check list or the like. Therefore, in such a processing apparatus, in the case where the operator carries out a plurality of works, an operator's omission of the work or error in the work sequence may be generated.

Accordingly, it is an object of the present invention to provide a processing apparatus capable of restraining an operator's omission of the work or error in the work sequence.

In accordance with an aspect of the present invention, there is provided a processing apparatus including: a touch panel that accepts an operator's operation; and a control unit that drives each of mechanisms by selection by the operator of an operation button displayed on the touch panel, in which the touch panel is configured to be able to display a progress confirmation screen where a plurality of the operation buttons are aligned, and displays the buttons which have been selected by the operator and which relevant to works that the operator has completed and the buttons which relevant to works that the operator has not completed in a discriminable manner.

When the operator selects the operation button and completes the work relevant to the operation button, an optional mark indicative of a carried-out state may be formed, or coloring may be conducted, on the carried-out operation button or the periphery thereof.

On the progress confirmation screen, an optional mark may be formed, or coloring may be conducted, on the operation button to be processed next by the operator or the periphery thereof.

On the progress confirmation screen, an optional mark may be formed, or coloring may be conducted, on the operation button the work relevant to which has not been completed by the operator or the periphery thereof.

The control unit may include a sequence storage section that stores a work sequence corresponding to each progress confirmation screen, and the progress confirmation screen may be designed such that the operation buttons cannot be selected in a sequence different from the work sequence.

The touch panel may be configured such that a work carrying-out screen, stringed to the operation button selected by the operator on the progress confirmation screen, having the operation buttons aligned according to a more detailed work sequence can be further displayed, and, when all the works corresponding to the operation buttons displayed on the work carrying-out screen have been completed by the operator, the operation buttons on the progress confirmation screen may be changed to a state of being discriminable as having been carried out.

The touch panel may be configured such that, in the case where the works corresponding to all the operation buttons aligned on the screen are not carried out and movement to other screen is conducted, the discriminable marks and coloring formed on the screen may be maintained as they are, and, when all the works corresponding to all the operation buttons aligned on the screen have been completed, the discriminable marks and the coloring may be removed.

The processing apparatus according to an aspect of the present invention is capable of restraining an operator's omission of the work or error in the work sequence.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view depicting a configuration example of a processing apparatus according to a first embodiment;

FIG. 2 is a diagram schematically depicting an example of functional configuration of the processing apparatus according to the first embodiment;

FIG. 3 is a diagram depicting an example of work sequence data stored in a sequence storage section of the processing apparatus according to the first embodiment;

FIGS. 4A, 4B, and 4C are diagrams depicting an example of screen display processing according to the first embodiment;

FIGS. 5A, 5B, and 5C are diagrams depicting an example of screen display processing according to the first embodiment;

FIGS. 6A, 6B, and 6C are diagrams depicting an example of screen display processing according to the first embodiment;

FIG. 7 is a diagram depicting an example of screen display processing according to a second embodiment; and

FIG. 8 is a diagram depicting an example of screen display processing according to a third embodiment.

### DETAILED DESCRIPTION OF THE PREFERRED EMBODIMENTS

Embodiments of the present invention will be described in detail below referring to the attached drawings. The present invention is not to be limited by the content described in the following embodiments. In addition, the components described below include those which can be easily conceived by a person skilled in the art and those which are substantially the same. Further, the configurations described below may be appropriately combined with one another. Besides, various kinds of omission, replacement, and modification of configuration can be performed within such ranges as not to depart from the gist of the present invention.

### First Embodiment

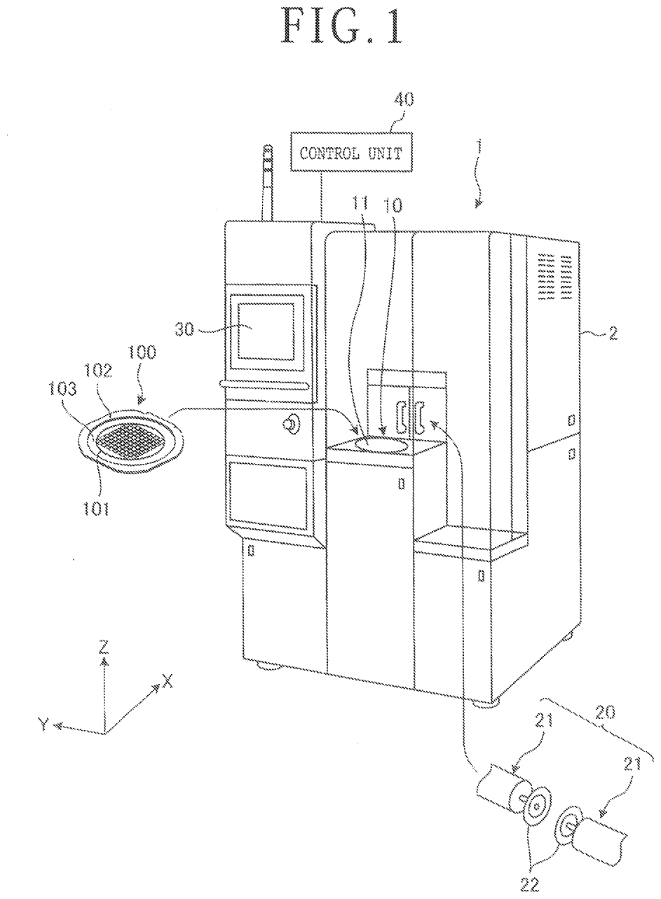

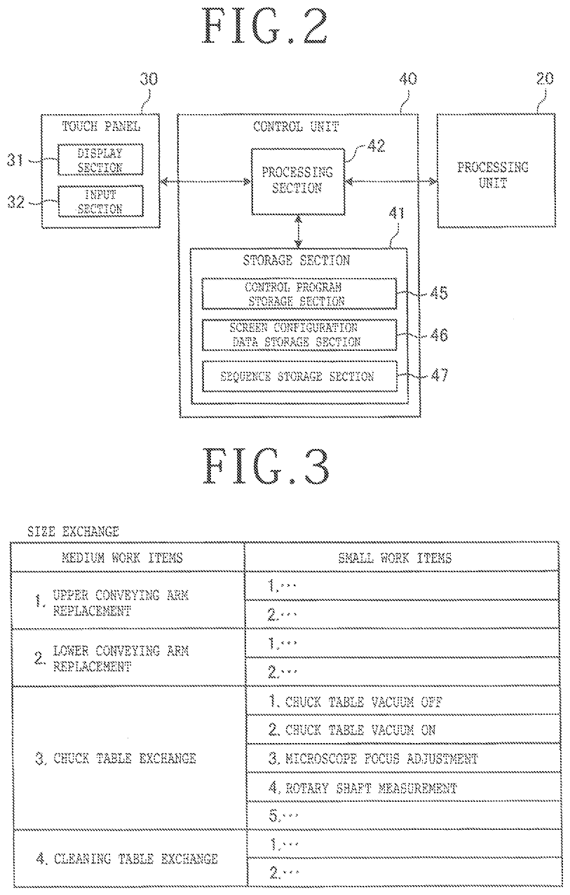

A processing apparatus 1 according to a first embodiment of the present invention will be described on the basis of the drawings. FIG. 1 is a perspective view depicting a configuration example of the processing apparatus 1 according to the first embodiment. FIG. 2 is a diagram schematically depicting an example of functional configuration of the processing apparatus 1 according to the first embodiment. As depicted in FIG. 1, the processing apparatus 1 according to the first embodiment includes a main body 2 which is a box-shaped housing. As illustrated in FIG. 1, the processing apparatus 1 includes a chuck table 10, a processing unit 20, a touch panel 30, and a control unit 40.

A workpiece 100 as an object of processing by the processing apparatus 1 includes, for example, a disk-shaped semiconductor wafer or optical device wafer with a substrate 101 including silicon, sapphire, gallium arsenide, or the like. The workpiece 100 is configured by supporting the substrate 101 at an opening of an annular frame 102 through an adhesive tape 103.

The chuck table 10 holds the workpiece 100 on a holding surface 11. The chuck table 10 communicates with a suction source (not illustrated), and suction holds the workpiece 100 by a negative pressure supplied from the suction source. The chuck table 10 is movable in an X-axis direction by an X-axis moving unit (not illustrated), and is rotatable around a Z-axis by a rotational drive source (not illustrated).

The processing unit 20 processes the workpiece 100 held by the chuck table 10. The processing unit 20 is, for example, a pair of cutting units 21, which each have a cutting blade 22. The respective cutting blades 22 of the pair of cutting unit 21 face each other in a Y-axis direction, and are each rotated around a Y-axis. The processing unit 20 performs cutting on the workpiece 100 by the rotating cutting blades 22. The processing unit 20 is movable along the Y-axis direction by a Y-axis moving unit (not illustrated), and is movable along the Z-axis direction by a Z-axis moving unit (not illustrated).

The processing apparatus 1 processes the workpiece 100 held by the chuck table 10 by relatively moving the chuck table 10 and the processing unit 20 by the X-axis moving unit, the Y-axis moving unit, and the Z-axis moving unit.

Note that the processing unit 20 included in the processing apparatus 1 is not limited to the cutting units 21 for cutting the workpiece 100 by the cutting blades 22. The processing unit 20 may be, for example, a grinding unit that grinds the similar workpiece 100 by a grindstone or the like, a polishing unit that polishes the similar workpiece 100 by a polishing pad or the like, or a laser processing unit that performs laser processing by applying a laser beam to the similar workpiece 100.

As illustrated in FIG. 1, the touch panel 30 is set on the main body 2 in a state in which a display surface is oriented to the outside. As depicted in FIG. 2, the touch panel 30 includes a display section 31 that displays various kinds of information concerning the processing apparatus 1, and an input section 32 that accepts from the operator various kinds of operation inputs concerning the processing apparatus 1, such as setting inputs of processing conditions.

The control unit 40 controls each of the mechanisms (the X-axis moving unit, the Y-axis moving unit, the Z-axis moving unit, the rotational drive source) that drive the processing apparatus 1. The control unit 40 controls each section of the processing apparatus 1, and realizes processing by the processing apparatus 1. The control unit 40 controls each section of the processing apparatus 1 inclusive of the chuck table 10 and the processing unit 20 according, for example, to the processing conditions inputted and set by the operator, thereby realizing a processing on the workpiece 100.

As depicted in FIG. 2, the control unit 40 includes a storage section 41, and a processing section 42. The control unit 40, in the first embodiment, includes a computer system.

The storage section 41 stores a program for realizing functions such as various kinds of processing in the processing apparatus 1 executed by the processing section 42, and data (processing conditions) used in processing by the program, and the like. The storage section 41 includes a nonvolatile or volatile semiconductor memory such as a random access memory (RAM), a read only memory (ROM), a flash memory, an erasable programmable read only memory (EPROM), an electrically erasable programmable read only memory (EEPROM) (registered trademark), and the like. The storage section 41 in which the program is stored is, for example, a storage medium including a plurality of commands for data processing executable by a processor included in the processing section 42 and readable by the processor and non-transitory, and can be also said to be a program product. The storage section 41 can be utilized also as a temporary working area at the time of executing the commands described in the program by the processor included in the processing section 42.

As depicted in FIG. 2, the storage section 41 includes a control program storage section 45, a screen configuration data storage section 46, and a sequence storage section 47.

A control program stored in the control program storage section 45 provides functions for realizing various kinds of processing of the processing apparatus 1, and the like. The functions provided by the control program includes screen display processing functions such as generating various kinds of operation screens, displaying the various kinds of operation screens on the touch panel 30, accepting inputs to the various kinds of operation screens on the touch panel 30, and changing over the various kinds of operation screens displayed on the touch panel 30 according to inputs to the various kinds of operation screens or the like.

The screen configuration data storage section 46 stores data concerning the screen configurations of the various kinds of operation screens displayed on the touch panel 30. The various kinds of operation screens displayed on the touch panel 30 includes screen configurations according to the kinds and versions of the programs operated by the processing apparatus 1.

The sequence storage section 47 stores, as work sequence data, data of each medium work necessary for executing each large work, in regard of each large work necessary for the operator to perform for realizing processing, on the basis of processing by the processing apparatus 1, and the sequence thereof, and data of each more detailed small work necessary for executing the medium works and the sequence thereof.

Here, the large works, medium works, and small works herein are expressions set by dividing the works of the operator into three hierarchies, for convenience of explanation, all of which are included in the works in the present invention. In addition, herein, the small work refers to individual works separated minutely, the medium work is a superordinate concept of the small work and refers to a group of a series of plurality of small works according to the sequence of the small works, and the large work is a superordinate concept of the medium work and refers to a group of a series of plurality of medium works according to the sequence of the medium works.

The work sequence data include each large work, items of each medium work (medium work items) on each large work basis, sequences of each medium work (medium work sequences) on each large work basis, items of each small work (small work items) on each medium work basis, and sequences of each small work (small work sequence) on each medium work basis, and these items correspond to one another.

FIG. 3 is a diagram depicting an example of work sequence data stored by the sequence storage section 47 of the processing apparatus 1 according to the first embodiment. FIG. 3 depicts a part concerning a large work “size exchange” carried out by the operator for changing the size of the workpiece 100 to be processed by the processing apparatus 1, of the work sequence data stored by the sequence storage section 47. Note that in FIG. 3, detailed descriptions of the small work items other than a third medium work item “chuck table replacement” in the medium work sequence and small work sequences thereof are omitted.

The processing section 42 includes a processor such as a central processing unit (CPU), a microprocessor, a microcomputer, a digital signal processor (DSP), or a system large scale integration (system LSI). The processor included in the processing section 42 executes a program loaded on the RAM included in the storage section 41. Thus, functions such as various kinds of processing to be carried out by the processing apparatus 1 are realized.

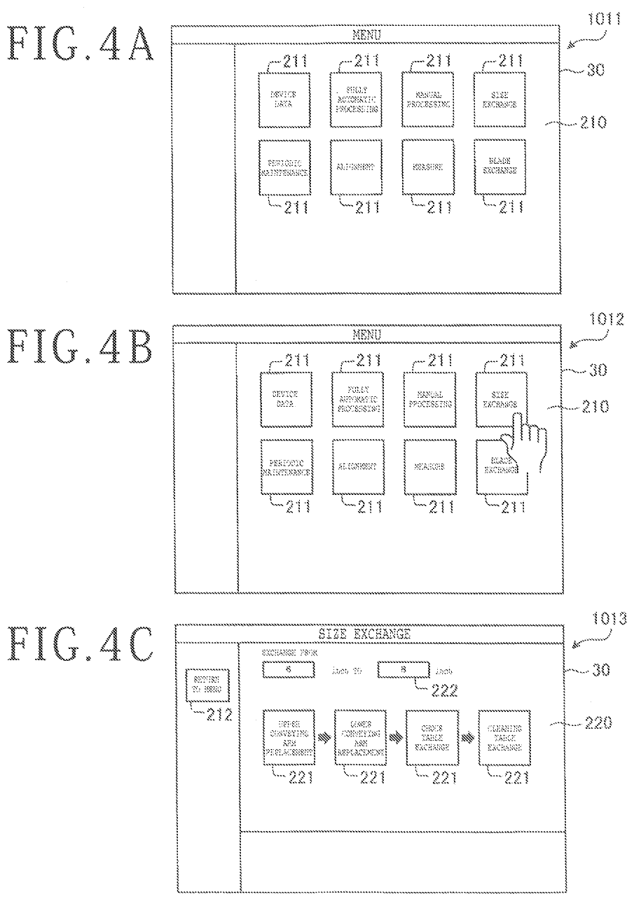

The processing section 42 operates on the basis of the program stored in the storage section 41, and carries out the screen display processing of the processing apparatus 1 described below. The processing section 42, with the operation buttons 211, 221, and 231 (see FIGS. 4, 5, and 6) displayed on the touch panel 30 being selected by the operator, in the screen display processing described below, each of functions constituting the processing apparatus 1 is driven according to the selected operation button 211, 221, and 231 (see FIGS. 4, 5, and 6).

FIGS. 4A, 4B, 4C, 5A, 5B, 5C, 6A, 6B, and 6C are diagrams depicting examples of the screen display processing according to the first embodiment. The screen display processing will be described specifically, using FIGS. 4A to 6C.

As illustrated in FIG. 4A, the processing section 42 displays a top menu screen 210 on the touch panel 30 according to an operator's operation (step 1011). The top menu screen 210 displays a plurality of operation buttons 211 for the operator to execute each large work necessary for carrying out each kind of processing of the processing apparatus.

The top menu screen 210 displays, on each operation button 211 displayed, a description such that the content of each large work carried out by an operator's operation is discriminable, in a superimposed state. Hereinafter, in the top menu screen 210, the operation button 211 operated by the operator for carrying out a predetermined large work will be referred to as an operation button 211 concerning the large work. The large works which can be carried out by the operator's operation of each operation button 211, in the first embodiment, include confirmation of device data of the processing apparatus 1, fully automatic processing of the workpiece 100, manual processing of the workpiece 100, size exchange of the workpiece 100 (work), periodic maintenance, alignment, various measurements, and replacement of the cutting blade 22.

As depicted in FIG. 4B, when the processing section 42 detects an operator's operation on the operation button 211 described as “size exchange” (step 1012), the processing section 42 displays the progress confirmation screen 220 concerning the large work “size exchange” on the touch panel 30 as depicted in FIG. 4C (step 1013). Note that the touch panel 30 has the progress confirmation screen 220 in the present invention means that the progress confirmation screen 220 can be displayed on the touch panel 30. In addition, herein, the progress confirmation screen 220 concerning a predetermined large work is a screen displayed when the operator operates the operation button 211 concerning the predetermined large work, and a screen which the operator refers to for carrying out the predetermined large work.

The progress confirmation screen 220 is generated by the processing section 42 by referring to the work sequence data stored in the sequence storage section 47. As depicted in FIG. 4C, the progress confirmation screen 220 displays a plurality of medium work items necessary for carrying out a large work concerning the progress confirmation screen 220, in the state of being aligned according to the medium work sequence. The progress confirmation screen 220 displays an input column 222 for information, in the case where inputting of the information from the operator is necessary for carrying out the large work. The progress confirmation screen 220 also displays a screen display switching button 212 for performing switching of the screen to the top menu screen 210.

The progress confirmation screen 220 is limited in regard of operation of the operation buttons 221 by the processing section 42, and is designed such that the operation buttons 221 cannot be selected in a sequence different from the medium work sequence. In other words, the progress confirmation screen 220 is designed such that the operation buttons 211 can be selected in a sequence according to the medium work sequence. The progress confirmation screen 220 is designed such that the operation buttons 221 can be selected by the operator, only in a state in which the medium works concerning all the operation buttons 221 in the former sequence have been completed.

The progress confirmation screen 220, like each operation button 211 on the top menu screen 210, displays on each operation button 221 a description such that the content of each medium work to be carried out by an operator's operation are discriminable, in a superimposed state. Hereinafter, in the progress confirmation screen 220, the operation button 221 operated by the operator for carrying out a predetermined medium work will be referred to as an operation button 211 concerning the medium work. The medium works which can be carried out by the operator's operation of each operation button 221 on the progress confirmation screen 220 concerning the large work “size exchange” include, in the first embodiment, replacement of an upper conveying arm of a conveying unit for conveying the workpiece 100 in the processing apparatus 1, replacement of a lower conveying arm of the conveying unit, exchange of the chuck table 10, and exchange of a cleaning table of a cleaning unit.

The processing section 42 can display on the touch panel 30 the progress confirmation screens 220 concerning all the large works which can be carried out by the operator's operation of each operation button 211. Note that hereinafter a case of carrying out screen display processing for the progress confirmation screen concerning the large work “size exchange” will be described, and descriptions of the progress confirmation screen 220 concerning other large works are similar to that of the case of the progress confirmation screen 220 concerning the large work “size exchange” and, therefore, will be omitted.

The progress confirmation screen 220 concerning the large work “size exchange” is stringed to the operation button 211 marked with “size exchange” and operated by the operator. Similarly, the progress confirmation screen concerning each large work is stringed to each operation button 211 marked with the content of the large work operated by the operator for displaying the progress confirmation screen 220.

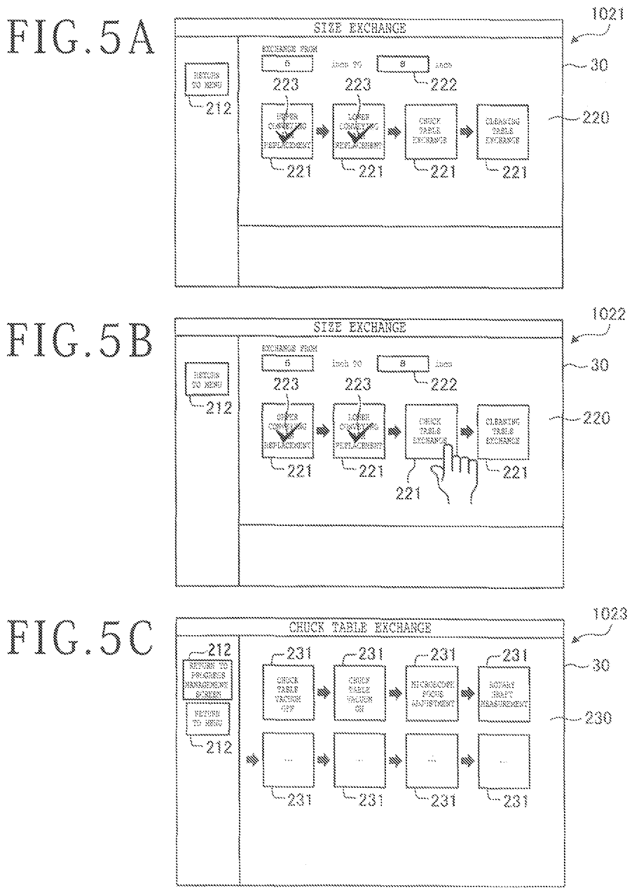

Next, when the operator selects the operation buttons 221 sequentially according to the medium work sequence, in regard of the two medium works “upper conveying arm replacement” and “lower conveying arm replacement” of the medium works necessary for the large work “size exchange” to thereby complete the medium works relevant to the operation buttons 221, the progress confirmation screen 220 as depicted in FIG. 5A is displayed on the touch panel 30 (step 1021). The progress confirmation screen 220 depicted in FIG. 5A displays the two operation buttons 221 concerning the medium works “upper conveying arm replacement” and “lower conveying arm replacement” which have been completed by the operator and the two operation buttons 221 concerning the medium works “chuck table exchange” and “cleaning table exchange” which have not been completed by the operator, in a discriminable manner.

The progress confirmation screen 220 depicted in FIG. 5A, in the first embodiment, displays a check mark 223 indicative of having been carried out, in a state of superimposing on the two operation buttons 221 concerning the medium works which have been completed by the operator. On the other hand, the progress confirmation screen 220 depicted in FIG. 5A does not display the check mark 223 indicating of having been carried out on the two operation buttons 221 concerning the medium works which have not been completed by the operator. Note that the progress confirmation screen 220 is not limited to this in the present invention, and a state in which an optional mark indicative of having been carried out may be formed, or a state in which coloring may be conducted, on the operation button 211 concerning a medium work which has been completed by the operator or the periphery thereof.

When an operator's operation on the operation button 221 marked with “chuck table exchange” is detected as depicted in FIG. 5B (step 1022), a work carrying-out screen 230 concerning the medium work “chuck table exchange” is displayed on the touch panel 30 as depicted in FIG. 5C (step 1023). Note that the touch panel 30 in the present invention includes the work carrying-out screen 230 means that the work carrying-out screen 230 can be displayed on the touch panel 30. In addition, herein, the work carrying-out screen 230 concerning a predetermined medium work is a screen displayed by the operator's operation of the operation button 221 concerning the predetermined medium work, and a screen which the operator refers to for carrying out a predetermined large work.

The work carrying-out screen 230 is generated by the processing section 42 by referring to the work sequence data stored in the sequence storage section 47, like the progress confirmation screen 220. As illustrated in FIG. 5C, the work carrying-out screen 230 displays a plurality of operation buttons 231 for carrying out a plurality of small work items necessary for carrying out a medium work concerning the work carrying-out screen 230, in a state of being aligned according to the small work sequence. The work carrying-out screen 230 also displays a plurality of screen display switching buttons 212 similar to those displayed on the top menu screen 210.

Like the progress confirmation screen 220, the work carrying-out screen 230 is limited in operation on the operation buttons 231 by the processing section 42, and is designed such that the operation buttons 231 cannot be selected in a sequence different from the small work sequence. In other words, the work carrying-out screen 230 is designed such that the operation buttons 231 can be selected only in a sequence according to the small work sequence. The work carrying-out screen 230 is designed such that the operation buttons 231 can be selected by the operator, only in a state in which the small works concerning all the operation buttons 231 in the former sequence has been completed.

The work carrying-out screen 230 displays a description such that the content of each small work to be carried out by an operator's operation is discriminable, in a state of superimposing on each operation button 231, similarly to each operation button 221 on the progress confirmation screen 220. Hereinafter, on the work carrying-out screen 230, the operation button 231 to be operated by the operator for carrying out a predetermined small work will be referred to as an operation button 231 concerning the small work. The small works which can be carried out by the operator by operating each operation button 231 on the work carrying-out screen 230 concerning the medium work “chuck table exchange” in the first embodiment include stopping of supply of a negative pressure to the chuck table 10 (OFF of vacuum of the chuck table 10), starting of supply of a negative pressure to the chuck table 10 (ON of vacuum of the chuck table 10), adjustment of focus of a microscope directed to the chuck table 10, measurement of a rotary shaft of the chuck table 10, and the like.

The processing section 42 can display on the touch panel 30 the work carrying-out screens 230 concerning all the medium works which can be carried out by the operator by operating each operation button 221. Note that in the case of a medium work for which the necessary small work is only one, the work carrying-out screen 230 concerning the medium work may be omitted, and a mode of completing with only the operation button 221 concerning the medium work may be adopted. Hereinafter, a case of carrying out screen display processing in regard of the work carrying-out screen 230 concerning the medium work “chuck table exchange” will be described, and the descriptions with respect to the work carrying-out screens 230 concerning other medium works are similar to those in the case of the work carrying-out screen 230 concerning the medium work “chuck table exchange” and, therefore, will be omitted.

The work carrying-out screen 230 concerning the medium work “chuck table exchange” is stringed to the operation button 221 marked with “chuck table exchange” operated by the operator. Similarly, the work carrying-out screen 230 concerning each medium work is stringed to each operation button 221 marked with the medium work operated by the operator for displaying the work carrying-out screen 230.

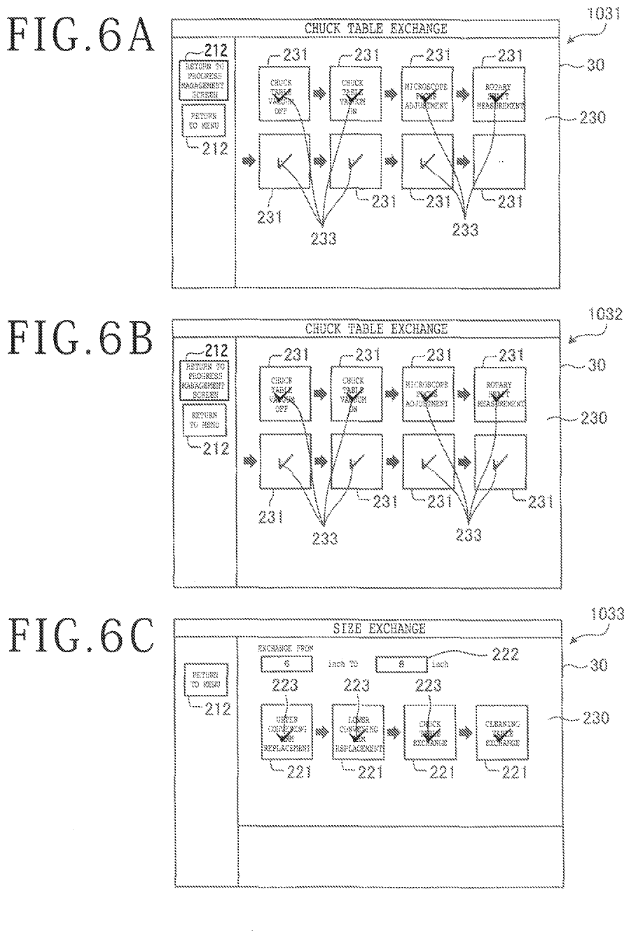

Next, in regard of seven small works of the small works necessary for the medium work “chuck table exchange,” when the operator sequentially selects the operation buttons 231 according to the small work sequence to complete the small works relevant to the operation buttons 231, the processing section 42 displays on the touch panel 30 the work carrying-out screen 230 as depicted in FIG. 6A (step 1031). Like the progress confirmation screen 220, the work carrying-out screen 230 depicted in FIG. 6A displays the seven operation buttons 231 concerning the small works completed by the operator and one operation button 231 concerning the small work not yet completed by the operator, in a discriminable manner.

In the first embodiment, the processing section 42 automatically determines completion of a small work based on the result of detection by a predetermined detector related to the small work and reflects it on the work carrying-out screen 230, but this is not restrictive of the present invention; an input indicative of completion of a small work to the touch panel 30 by the operator having carried out the small work may be accepted, and it may be reflected on the work carrying-out screen 230.

Like the progress confirmation screen 220, in the first embodiment, the work carrying-out screen 230 depicted in FIG. 6A displays check marks 233 indicative of having been carried out, in a state of superimposing on the seven operation buttons 231 concerning the small works completed by the operator. Note that the work carrying-out screen 230, like the progress confirmation screen 220, this is not restrictive of the present invention; a state in which an optional mark indicative of having been completed may be formed, or a state of coloring may be displayed, on the operation button 231 concerning a medium work which has been completed by the operator or the periphery thereof.

Then, when in regard of the final one small work of the small works necessary for the medium work “chuck table exchange,” the operator selects the operation button 231 to complete the small work relevant to the operation button 231, the processing section 42 displays on the touch panel 30 the work carrying-out screen 230 in a state in which the check marks 233 are displayed on the operation buttons 231 concerning all the small works (step 1032). When step 1032 is carried out, the processing section 42 adds a display of the check mark 223 on the operation button 221 concerning the medium work “chuck table exchange” on the progress confirmation screen 220, as depicted in FIG. 6C, and changes the operation button 221 concerning the medium work “chuck table exchange” into a state of being discriminable as having been carried out (step 1033).

In this way, the processing section 42, by confirming completion of all the small works corresponding to the medium work, automatically determines completion of the medium work, and reflects it on the progress confirmation screen 220.

In the case where in regard of an optional large work, the operator does not perform the works (medium works, small works) with respect to all the operation buttons 221 and 231 aligned on the progress confirmation screen 220 or the work carrying-out screen 230 but moves to other screen, namely, switches the display to other screen, the processing section 42 maintains the discriminable marks such as the check marks 223 and 233 or the coloring formed on the progress confirmation screen 220 or the work carrying-out screen 230 as they are. In regard of an optional large work, when the operator completes the works (medium works, small works) with respect to all the operation buttons 221 and 231 aligned on the progress confirmation screen 220 or the work carrying-out screen 230, the processing section 42 removes the discriminable marks such as the check marks 223 and 233 or the coloring formed on the progress confirmation screen 220 or the work carrying-out screen 230.

In the processing apparatus 1 according to the first embodiment having the aforementioned configuration, the touch panel 30 has the progress confirmation screen 220 on which a plurality of operation buttons 221 are aligned according to the work sequence (medium work sequence), and displays the operation buttons 221 which the operator has selected and the works (medium works) relevant to which have been completed and the operation buttons 221 the works (medium works) relevant to which have not been completed by the operator, in a discriminable manner. Therefore, the processing apparatus 1 according to the first embodiment makes it possible for the operator to intuitively and easily recognize the completed works (medium works) and the non-completed works (medium works) by looking at the touch panel 30, and produces an effect that an operator's omission of the work or error in the work sequence can be restrained.

In addition, in the processing apparatus 1 according to the first embodiment, when the operator selects the operation buttons 221 and completes the works (medium works) relevant to the operation buttons 221, optional marks such as check marks 223 indicative of having been completed are formed, or coloring is conducted, on the operation buttons 221 concerning the works (medium works) having been carried out and completed or the periphery thereof, on the progress confirmation screen 220. Therefore, the processing apparatus 1 according to the first embodiment produces an effect that it is possible for the operator to more intuitively and more easily recognize the completed works (medium works) and the non-completed works (medium works) by looking at the touch panel 30.

Besides, in the processing apparatus 1 according to the first embodiment, the control unit 40 includes the sequence storage section 47 that stores work sequences (medium work sequences) corresponding to each progress confirmation screen 220, and the progress confirmation screen 220 is designed such that the operation buttons 221 cannot be selected in a sequence different from the work sequences (medium work sequences). Therefore, in the processing apparatus 1 according to the first embodiment, the operator is restrained from performing the works (medium works) in a sequence different from the work sequences (medium work sequences), due to the limit in selection designed on the progress confirmation screen 220, so that an effect is produced that an operator's omission of the work or error in the work sequence can be restrained more securely.

In addition, in the processing apparatus 1 according to the first embodiment, the touch panel 30 further includes the work carrying-out screen 230 having the operation buttons 231 aligned according to a more detailed work sequence (small work sequence), which is stringed to the operation button 221 selected by the operator on the progress confirmation screen 220, and, when the operator completes all the works (small works) corresponding to the operation buttons 231 displayed on the work carrying-out screen 230, the operation button 221 on the progress confirmation screen 220 is changed to a state of being discriminable as having been carried out. Therefore, the processing apparatus 1 according to the first embodiment produces an effect that, owing to the management on a more detailed work level by the work carrying-out screen 230, an operator's omission of the work or error in the work sequence can be restrained more securely.

Besides, in the processing apparatus 1 according to the first embodiment, in the case where the works (medium works, small works) with respect to all the operation buttons 221 and 231 aligned on the progress confirmation screen 220 or the work carrying-out screen 230 are not performed but the touch panel 30 moves to other screen, the discriminable marks such as the check marks 223 and 233, or coloring, formed on the progress confirmation screen 220 or the work carrying-out screen 230 is maintained as it is, and, when the works (medium works, small works) with respect to all the operation buttons 221 and 231 aligned on the progress confirmation screen 220 or the work carrying-out screen 230 have been completed, the discriminable marks such as the check marks 223 and 233, or the coloring, formed on the progress confirmation screen 220 or the work carrying-out screen 230 is removed. Therefore, the processing apparatus 1 according to the first embodiment, owing to management of the marks or coloring indicative of completion or non-completion of the works (medium works, small works), an effect is produced that an operator's omission of the work or error in the work sequence can be restrained more securely.

### Second Embodiment

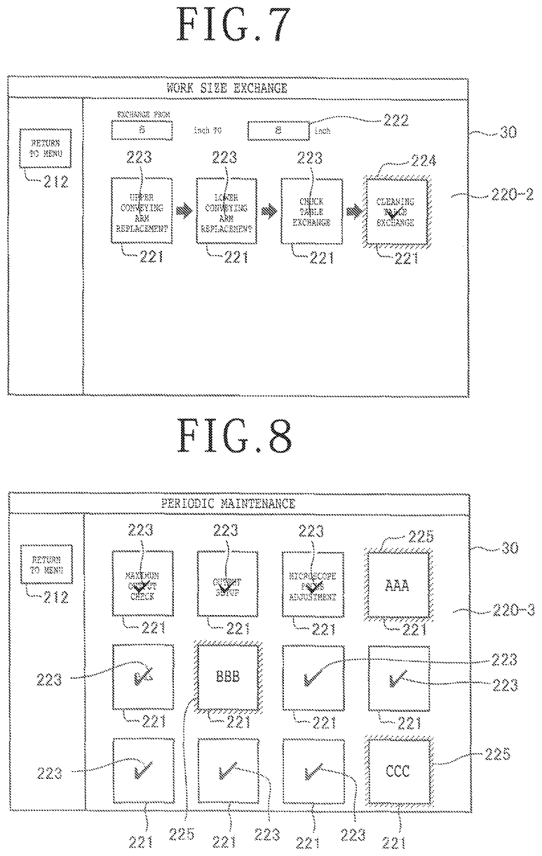

A processing apparatus 1 according to a second embodiment of the present invention will be described below on the basis of the drawings. FIG. 7 is a diagram depicting an example of screen display processing according to the second embodiment. In FIG. 7, the same parts as those in the first embodiment above are denoted by the same reference symbols as used above, and descriptions thereof are omitted.

The processing apparatus 1 according to the second embodiment is the processing apparatus 1 according to the first embodiment, in which a progress confirmation screen 220-2 depicted in FIG. 7 is displayed in place of the progress confirmation screen 220 depicted in FIG. 6C.

As illustrated in FIG. 7, the progress confirmation screen 220-2 displays by applying a coloring 224 that draws the operator's attention to the operation button 221 concerning the medium work “cleaning table exchange” to be processed next by the operator, to the periphery of the operation button 221. Note that the progress confirmation screen 220-2 is not limited to this in the present invention; an optional mark or a coloring that draws the operator's attention to the operation button 221 concerning the medium work to be processed next by the operator may be formed on the operation button 221 or the periphery thereof. In addition, in the second embodiment, like the progress confirmation screen 220-2, the work carrying-out screen 230 may display an optional mark or a coloring that draws the operator's attention to the operation button 231 concerning the small work to be processed next by the operator on the operation button 231 or the periphery thereof.

In the processing apparatus 1 according to the second embodiment having the aforementioned configuration, as compared to the processing apparatus 1 according to the first embodiment, an optional mark, or coloring, that draws the operator's attention to the operation buttons 221 and 231 concerning the works (medium works, small works) to be processed next by the operator is formed on the operation buttons 221 and 231 or the periphery thereof, on the progress confirmation screen 220-2 or the work carrying-out screen 230. Therefore, the processing apparatus 1 according to the second embodiment makes it possible for the operator to intuitively and easily recognize the work (medium work, small work) to be processed next by the operator, so that an effect is produced that an operator's omission of the work or error in the work sequence can be restrained.

### Third Embodiment

A processing apparatus 1 according to a third embodiment will be described on the basis of the drawings. FIG. 8 is a diagram depicting an example of screen display processing according to the third embodiment. In FIG. 8, the same parts as those in the first embodiment above are denoted by the same reference symbols as used above, and descriptions thereof are omitted.

The processing apparatus 1 according to the third embodiment is the processing apparatuses 1 in the first and second embodiments, in which a progress confirmation screen 220-3 depicted in FIG. 8 is further displayed.

When an operator's operation on the operation button 211 marked with “periodic maintenance” is detected, the processing section 42 displays on the touch panel 30 the progress confirmation screen 220-3 concerning the large work “periodic maintenance,” as depicted in FIG. 8. Note that in the third embodiment, since a medium work sequence is not set for the medium works belonging to the large work “periodic maintenance,” the progress confirmation screen 220-3 does not display the operation buttons 221 in a state of being aligned according to the medium work sequence, and limit on operations by the medium work sequence is not designed; however, in the case where medium works and the small works are set, the progress confirmation screen or the work carrying-out screen may be displayed like in the first and second embodiments. The medium works which can be carried out by the operator by operating the operation buttons 221 on the progress confirmation screen 220-3 concerning the large work “periodic maintenance” in the third embodiment include maximum output check of a spindle rotating the cutting blade 22 or the like, output setup of the spindle or the like, adjustment of focus of a microscope directed to the chuck table 10, and the like.

As illustrated in FIG. 8, the progress confirmation screen 220-3 displays a coloring 225 that draws the operator's attention to the three operation buttons 221 concerning the medium works “AAA” “BBB” “CCC” the operator's works relevant to which have not been completed, in the periphery of the operation buttons 221. Note that the progress confirmation screen 220-3 is not restricted to this in the present invention; an optional mark, or coloring, that draws the operator's attention to the operation button 221 concerning the medium work the operator's work relevant to which has not been completed may be formed on the operation button 221 or the periphery thereof. In addition, a similar display may be made for small works, also.

In addition, in regard of the medium works belonging to the large work “periodic maintenance,” in the case where a predetermined period is elapsed from final completion of the operator's medium work and the work becomes necessary again, for example, one month is elapsed, it is preferable to remove the marks such as check marks 223 or coloring indicative of having been carried out that is formed on the operation buttons 221 concerning medium works, and switches the display to a display of a mark or coloring such as a coloring 225 that draws the operator's attention and urges the operator to carry out. By switching the display in this way, the progress confirmation screen 220-3 can cause the operator to securely carry out the medium works belonging to the large work “periodic maintenance” once a predetermined period, for example, once in one month.

The processing apparatus 1 according to the third embodiment having the aforementioned configuration, as compared to the processing apparatuses 1 according to the first and second embodiments, further in regard of the progress confirmation screen 220-3, optional marks or coloring that draws the operator's attention to the operation buttons 221 the operator's works (medium works) relevant to which have not been completed is formed on the operation buttons 221 or the periphery thereof. Therefore, the processing apparatus 1 according to the third embodiment makes it possible for the operator to intuitively and easily recognize the works (medium works) not completed by the operator, so that an effect is produced that an operator's omission of the work or error in the work sequence can be restrained.

Note that the present invention is not limited to the aforementioned embodiments and modifications. In other words, the present invention may be carried out with various modifications within such ranges as not depart from the gist of the invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A processing apparatus comprising:
a touch panel that accepts an operator's operation; and
a control unit that drives each of mechanisms by selection by the operator of an operation button displayed on the touch panel,
wherein the touch panel
is configured to be able to display a progress confirmation screen where a plurality of the operation buttons are aligned, and
displays the buttons which have been selected by the operator and which relevant to works that the operator has completed and the buttons which relevant to works that the operator has not completed in a discriminable manner.

2. The processing apparatus according to claim 1, wherein, when the operator selects the operation button and completes the work relevant to the operation button, an optional mark indicative of a carried-out state is formed, or coloring is conducted, on the carried-out operation button or a periphery thereof.

3. The processing apparatus according to claim 1, wherein, on the progress confirmation screen, an optional mark is formed, or coloring is conducted, on the operation button to be processed next by the operator or the periphery thereof.

4. The processing apparatus according to claim 1, wherein, on the progress confirmation screen, an optional mark is formed, or coloring is conducted, on the operation button the work relevant to which has not been completed by the operator or the periphery thereof.

5. The processing apparatus according to claim 1,
wherein the control unit
includes a sequence storage section that stores a work sequence corresponding to each progress confirmation screen, and
the progress confirmation screen is
designed such that the operation buttons are unable to be selected in a sequence different from the work sequence.

6. The processing apparatus according to claim 1,
wherein the touch panel is
configured such that a work carrying-out screen, stringed to the operation button selected by the operator on the progress confirmation screen, having the operation buttons aligned according to a more detailed work sequence is able to be further displayed, and
when all the works corresponding to the operation buttons displayed on the work carrying-out screen have been completed by the operator, the operation buttons on the progress confirmation screen are changed to a state of being discriminable as having been carried out.

7. The processing apparatus according to claim 1,
wherein the touch panel is
configured such that, in a case where the works corresponding to all the operation buttons aligned on the screen are not carried out and movement to other screen is conducted, the discriminable marks and coloring formed on the screen are maintained as they are, and, when all the works corresponding to all the operation buttons aligned on the screen have been completed, the discriminable marks and the coloring are removed.

8. The processing apparatus according to claim 2, wherein, on the progress confirmation screen, an optional mark is formed, or coloring is conducted, on the operation button to be processed next by the operator or the periphery thereof.

9. The processing apparatus according to claim 2, wherein, on the progress confirmation screen, an optional mark is formed, or coloring is conducted, on the operation button the work relevant to which has not been completed by the operator.

10. The processing apparatus according to claim 2,
wherein the control unit
includes a sequence storage section that stores a work sequence corresponding to each progress confirmation screen, and
the progress confirmation screen is
designed such that the operation buttons are unable to be selected in a sequence different from the work sequence.

11. The processing apparatus according to claim 2,
wherein the touch panel is
configured such that a work carrying-out screen, stringed to the operation button selected by the operator on the progress confirmation screen, having the operation buttons aligned on a more detailed work sequence is able to be further displayed, and
when all the works corresponding to the operation buttons displayed on the work carrying-out screen have been completed by the operator, the operation buttons on the progress confirmation screen are changed to a state of being discriminable as having been carried out.

12. The processing apparatus according to claim 2,
wherein the touch panel is
configured such that in a case where the works corresponding to all the operation buttons aligned on the screen are not carried out and movement to other screen is conducted, the discriminable marks and coloring formed on the screen are maintained as they are, and, when all the works corresponding to all the operation buttons aligned on the screen have been completed, the discriminable marks and the coloring are removed.
